(19) United States
(12) Patent Application Publication
(10) Pub. No.: US 2026/0304616 A1
(43) Pub. Date: Oct. 1, 2026

(54) CONDUCTIVE SUBSTRATE AND MANUFACTURING METHOD THEREOF

(71) Applicant: DeepWave, Inc., Santa Clara, CA (US)

(72) Inventors: Dae-kyu CHOI, Suwon-si (KR); Kuk Hwan LEE, Suwon-si (KR)

(73) Assignee: DeepWave, Inc., Santa Clara, CA (US)

(21) Appl. No.: 19/094,094

(22) Filed: Mar. 28, 2025

(51) Int. Cl. H05K 1/05; H05K 1/11; H05K 3/10

(52) U.S. Cl. CPC H05K 1/05; H05K 1/115; H05K 3/10; H05K 2201/09036; H05K 2203/107

(57) ABSTRACT

A silicon-based conductive substrate according to the present disclosure includes an undoped or regionally non-uniformly doped silicon substrate, an insulating layer located on the silicon substrate, and a metal pattern located on the insulating layer.

### BACKGROUND OF THE INVENTION

### 1. Field of the Invention

The present disclosure relates to a conductive substrate and a manufacturing method thereof.

### 2. Description of the Related Art

A conductive substrate is a substrate that can provide a conductive pathway for current flow. A conductive substrate is utilized in various fields, and used in, for example, semiconductor elements, solar cells, display devices, and other electronic circuits.

With recent technological advancements and increasing demands for higher performance products, various types of conductive substrates are being developed.

### SUMMARY OF THE INVENTION

Aspects of the present disclosure provide a conductive substrate that provides a conductive path with reduced manufacturing cost and high reliability.

Aspects of the present disclosure also provide a manufacturing method of a conductive substrate.

It will be understood that technical problems of the present disclosure are not limited to the aforementioned problems and other technical problems not referred to herein will be clearly understood by those skilled in the art from disclosures below.

According to an embodiment of the present disclosure, there is provided a silicon-based conductive substrate comprising: an undoped or regionally non-uniformly doped silicon substrate; an insulating layer located on the silicon substrate; and a metal pattern located on the insulating layer.

The silicon substrate may be an undoped silicon substrate, and a silicon purity of the silicon substrate may be 99.99999999% or less.

The silicon substrate may not substantially contain a boron (B) element and a phosphorus (P) element.

The silicon substrate may have a polycrystalline structure, and the purity of the silicon substrate may be 99.99% or more.

The silicon substrate may be partially doped with boron (B) or phosphorus (P) to become a non-uniformly doped silicon substrate.

The silicon substrate may contain a nitrogen (N) or oxygen (O) element, and a resistivity of the silicon substrate may range from several hundred Ω·cm to several thousand Ω·cm.

The silicon substrate may have a band gap of 9.1 eV or more, or a breakdown voltage of 10 MV/cm or more.

The insulating layer may contain at least one of silicon dioxide (SiO₂), silicon nitride (Si₃N₄), or silicon oxynitride (SiOxNy, where x and y are the same or different numbers).

The metal pattern may contain at least one of copper (Cu), silver (Ag), gold (Au), aluminum (Al), or tungsten (W).

The silicon substrate may have a via hole, the insulating layer may be located on an inner sidewall of the via hole, and the metal pattern may be located within the via hole.

The metal pattern may be arranged on a first surface and a second surface of the silicon substrate, and the metal pattern on the first surface and the metal pattern on the second surface may be electrically connected to each other.

The metal pattern may be formed by laser patterning.

The metal pattern may be formed by printing a metal paste.

The silicon substrate may comprise a first silicon substrate and a second silicon substrate physically separated from the first silicon substrate, the insulating layer may comprise a first insulating layer located on the first silicon substrate and a second insulating layer located on the second silicon substrate, the metal pattern may comprise a first metal pattern in contact with the first insulating layer, and a second metal pattern in contact with the second insulating layer, and the metal pattern may further comprise a third metal pattern in contact with the first silicon substrate and the second silicon substrate, or located between the first silicon substrate and the second silicon substrate.

The third metal pattern may be in contact with a top surface of the first silicon substrate and a top surface of the second silicon substrate.

A first groove may be formed on a surface of the first silicon substrate facing the second silicon substrate, a second groove may be formed on a surface of the second silicon substrate facing the first silicon substrate, the first groove and the second groove may together form a coupling hole, and the third metal pattern may be filled in the coupling hole.

The silicon substrate may comprise a first silicon substrate and a second silicon substrate physically separated from the first silicon substrate and stacked on the first silicon substrate, the insulating layer may comprise a first insulating layer located on the first silicon substrate and a second insulating layer located on the second silicon substrate, the metal pattern may comprise a first metal pattern in contact with the first insulating layer, and a second metal pattern in contact with the second insulating layer, and the first metal pattern and the second metal pattern may be at least partially in contact with each other and electrically connected.

The first silicon substrate and the second silicon substrate may each have a first via hole and a second via hole, and at least some of the first via hole and the second via hole may be matched and aligned in the stacking direction or may be mismatched and misaligned.

According to an embodiment of the present disclosure, there is provided a manufacturing method of a conductive substrate, comprising: preparing an undoped or regionally non-uniformly doped silicon substrate; placing an insulating layer on the silicon substrate; and placing a metal pattern on the insulating layer.

Specific details of other embodiments are included in the detailed description.

According to embodiments of the present disclosure, a reliable conductive substrate including a detailed conductive pattern may be provided in a relatively simple manner.

The effects according to the embodiments of the present disclosure are not limited to the contents exemplified above.

### BRIEF DESCRIPTION OF THE DRAWINGS

The above and other objects, features, and advantages of the present disclosure will be more clearly understood from the following detailed description taken in conjunction with the accompanying drawings, in which:

FIGS. 1 to 10 are diagrams illustrating a conductive substrate and a manufacturing method thereof according to an embodiment of the present disclosure.

FIGS. 11 to 15 are diagrams illustrating a conductive substrate and a manufacturing method thereof according to another embodiment of the present disclosure.

FIGS. 16 to 19 are diagrams illustrating a conductive substrate and a manufacturing method thereof according to still another embodiment of the present disclosure.

FIG. 20 is a cross-sectional schematic diagram of a conductive substrate according to still another embodiment of the present disclosure.

FIGS. 21 and 22 are diagrams illustrating a conductive substrate and a manufacturing method thereof according to still another embodiment of the present disclosure.

FIGS. 23 and 24 are diagrams illustrating a conductive substrate and a manufacturing method thereof according to still another embodiment of the present disclosure.

FIG. 25 is a cross-sectional schematic diagram of a conductive substrate according to still another embodiment of the present disclosure.

FIG. 26 is a cross-sectional schematic diagram of a conductive substrate according to still another embodiment of the present disclosure.

### DETAILED DESCRIPTION OF THE INVENTION

Advantages and features of the present disclosure and methods of accomplishing the same may be understood more readily by reference to the following detailed description of preferred embodiments and the accompanying drawings. The present disclosure may, however, be embodied in many different forms and should not be construed as being limited to the embodiments set forth herein. Rather, these embodiments are provided to convey the concept of the disclosure to those skilled in the art.

Various changes may be made to embodiments presented in the present disclosure. Examples described below are not intended to limit embodiments of the present disclosure, and should be understood to include all modifications, equivalents, or alternatives thereto.

As used herein, the term “and/or” includes any and all combinations of one or more of the associated listed items. As used herein, the singular forms “a”, “an” and “the” are intended to include the plural forms as well, unless clearly stated otherwise. It will be further understood that the terms “comprises” and/or “comprising,” when used in this specification, specify the presence of stated components, but do not preclude the presence or addition of one or more other components. A numerical range expressed using “to” indicates a numerical range including values stated before and after “to” as the lower and upper limits. A numerical range expressed using “about” or “approximately” indicates a value or a numerical range within 20% of the value or the numerical range stated after “about” or “approximately”.

In this specification, ordinal modifiers such as “first component”, “second component”, “first-first component”, etc., when referring to components, are only used to distinguish one component from another. Therefore, the first component referred to below may be referred to as the second component within the scope of the present disclosure. For example, what is referred to as the first component in one embodiment may be referred to as the second component in another embodiment.

In the drawings, the present disclosure is not limited to the illustrated form and components may be enlarged or reduced in size, thickness, width, length, and the like.

Spatially relative terms, such as “above,” “upper,” “on,” “below,” “beneath,” “lower,” and the like, may be used herein for ease of description to describe one element or feature's relationship to another element(s) or feature(s) as illustrated in the figures. It will be understood that the spatially relative terms may encompass a different orientation of the device other than the orientation depicted in the figures. For example, if the device in the figures is turned over, elements described as “below” or “beneath” other elements or features would then be oriented “above” the other elements or features.

The first direction X means any direction on the plane, and the second direction Y means another direction intersecting or orthogonal to the first direction X within the plane. The third direction Z means another direction intersecting or perpendicular to the plane. The term “overlap” or “overlapping” may be understood to mean one or more components or features are aligned or positioned along at least one common direction. For example, if a first component and a second component are positioned along a same X-direction, where the first component is positioned before or after the second component along the X-direction, the first component and the second component may be considered to overlap in the X-direction.

Hereinafter, the present disclosure is described in detail with reference to the accompanying drawings.

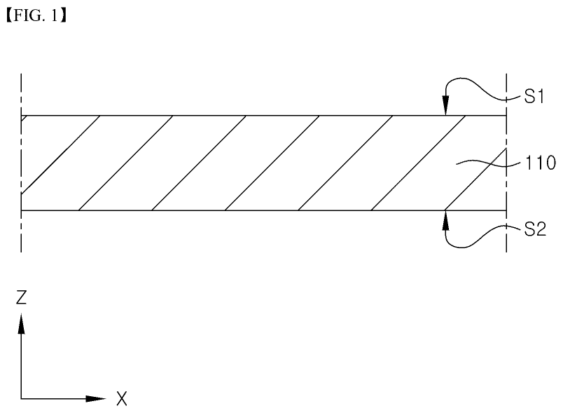

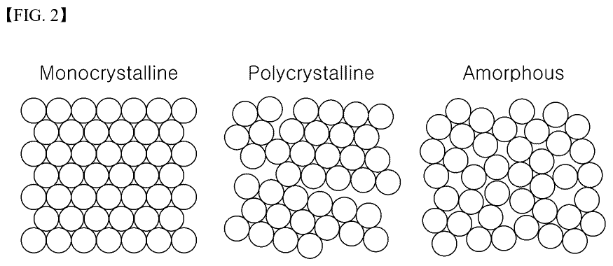

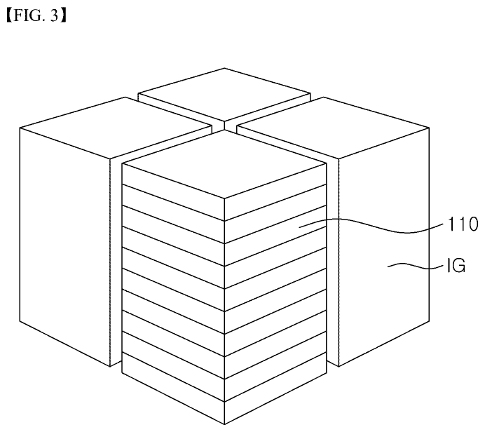

FIGS. 1 to 10 are diagrams illustrating a conductive substrate and a manufacturing method thereof according to an embodiment of the present disclosure. FIG. 2 is a schematic diagram illustrating polycrystalline, monocrystalline, and amorphous structures that may be used as a silicon substrate 110 according to the present disclosure. FIG. 3 illustrates an ingot IG for obtaining the silicon substrate 110.

First, referring to FIGS. 1 to 3, the silicon substrate 110 may be prepared. The silicon substrate 110 may be a silicon substrate, which is substantially undoped (without doping), for example, a silicon wafer. That is, the silicon substrate 110 may not substantially contain boron (B) and/or phosphorus (P) elements, or may contain only unintended trace amounts of boron and/or phosphorus.

The silicon purity of the silicon substrate 110 may be about 99.99999999% or less. The lower limit of the purity of the silicon substrate 110 may be about 99.99% or more, about 99.999% or more, about 99.9999% or more, about 99.99999% or more, about 99.999999% or more, or about 99.9999999% or more.

When the purity of the silicon substrate 110 is within the above range, the silicon substrate 110 may further include one or more elements selected from oxygen (O), carbon (C), iron (Fe), aluminum (Al), copper (Cu), calcium (Ca), boron (B), phosphorus (P), nitrogen (N), and sulfur(S). In an exemplary embodiment, the impurity concentration of the group consisting of oxygen (O), carbon (C), iron (Fe), aluminum (Al), copper (Cu), calcium (Ca), boron (B), phosphorus (P), nitrogen (N), and sulfur(S) in the silicon substrate 110 may be about 0.0000001% or more and 0.01% or less, about 0.0000001% or more and 0.001% or less, about 0.0000001% or more and 0.0001% or less, about 0.0000001% or more and 0.00001% or less, or about 0.0000001% or more and 0.000001% or less.

As a non-limiting example, the silicon substrate 110 as a whole may have the concentration of each of boron elements and phosphorus elements, which is about 10¹⁴ atoms/cm³ or less, about 10¹³ atoms/cm³ or less, about 10¹² atoms/cm³ or less, about 10¹¹ atoms/cm³ or less, about 10¹⁰ atoms/cm³ or less, about 10⁹ atoms/cm³ or less, about 10⁸ atoms/cm³ or less, about 10⁷ atoms/cm³ or less, about 10⁶ atoms/cm³ or less, or about 10⁵ atoms/cm³ or less.

The silicon substrate 110 may have a monocrystalline, polycrystalline, or amorphous structure. The atomic structures having monocrystalline, polycrystalline and amorphous structures are illustrated in FIG. 2. Preferably, the silicon substrate 110 may have a polycrystalline structure or an amorphous structure. More preferably, the silicon substrate 110 may have a polycrystalline structure.

In some embodiments, the silicon substrate 110 has a polycrystalline structure and may be prepared by cutting the ingot IG having a rectangular parallelepiped shape rather than a cylindrical shape as illustrated in FIG. 3. The silicon substrate 110 having a larger size may be obtained by cutting the ingot IG having a rectangular parallelepiped shape. For example, the length of any minimum side of the silicon substrate 110 having a square or rectangular shape may be about 600 mm or more, about 700 mm or more, about 800 mm or more, about 900 mm or more, or about 1,000 mm or more. In some embodiments, when polycrystalline silicon is used as the silicon substrate 110, a larger area substrate may be obtained, and the electrical conductivity may be relatively low compared to a monocrystalline structure or the like, which may be advantageous.

In another embodiment, the silicon substrate 110 may be the substantially undoped silicon substrate that is only partially doped with impurities. That is, the silicon substrate 110 may be a silicon substrate that is regionally non-uniformly doped. In other words, the purity of silicon in an undoped arbitrary unit area of the silicon substrate 110, for example, an area of 1.0 cm² or a volume of 1.0 cm³, may be about 99.99% to 99.99999999%. And the purity of silicon in a doped arbitrary unit area may be lower than that.

For example, the unit area of any region (undoped region) of the silicon substrate 110 may be substantially undoped as described above, and the concentration of impurity elements (e.g., elements of the group consisting of oxygen (O), carbon (C), iron (Fe), aluminum (Al), copper (Cu), calcium (Ca), boron (B), phosphorus (P), nitrogen (N), and sulfur (S)) may be about 0.0000001% or more and 0.01% or less, about 0.0000001% or more and 0.001% or less, about 0.0000001% or more and 0.0001% or less, about 0.0000001% or more and 0.00001% or less, or about 0.0000001% or more and 0.000001% or less.

Alternatively, the undoped region may contain each of boron elements and phosphorus elements, at a concentration of about 10¹⁴ atoms/cm³ or less, about 10¹³ atoms/cm³ or less, about 10¹² atoms/cm³ or less, about 10¹¹ atoms/cm³ or less, about 10¹⁰ atoms/cm³ or less, about 10⁹ atoms/cm³ or less, about 10⁸ atoms/cm³ or less, about 10⁷ atoms/cm³ or less, about 10⁶ atoms/cm³ or less, or about 10⁵ atoms/cm³ or less.

On the other hand, the unit area of another region (doped region) of the silicon substrate 110 may be partially doped with an impurity element such as a boron element and/or a phosphorus element, and the concentration of the impurity element per unit area may be about 0.000001% or more, about 0.00001% or more, about 0.0001% or more, about 0.001% or more, or about 0.01% or more.

Alternatively, in the doped region, the concentration of at least one of boron elements and phosphorus elements may be about 10¹⁵ atoms/cm³ or more, or about 10¹⁶ atoms/cm³ or more. The upper limit of the concentration of a boron element or a phosphorus element may be, for example, about 10²⁰ atoms/cm³ or less. An electrode is provided on the doped region, and the doped region can function as an electron channel.

In other words, the concentration of a boron or phosphorus element in an arbitrary region (e.g., the doped region described above) may be about 1.2 times or more, about 1.4 times or more, about 1.6 times or more, about 1.8 times or more, or about 2 times or more the concentration of the element in another arbitrary region (e.g., the undoped region).

In an exemplary embodiment, the resistivity of the substantially undoped or partially doped silicon substrate 110 described above may range from several hundred Ω·cm to several thousand Ω·cm. That is, the lower limit of resistivity may be about 100 Ω·cm, about 500 Ω·cm, or about 999 Ω·cm. Additionally, the upper limit of resistivity may be about 9,999 Ω·cm, about 5,000 Ω·cm, or about 1,000 Ω·cm.

Additionally, the band gap of the silicon substrate 110 may be very large, such as 9.1 eV or more. Here, the band gap may mean the difference between the valence band and the conduction band. The breakdown voltage of the silicon substrate 110 may be 10 MV/cm or more. Here, the breakdown voltage may mean the voltage at which the insulation properties are lost.

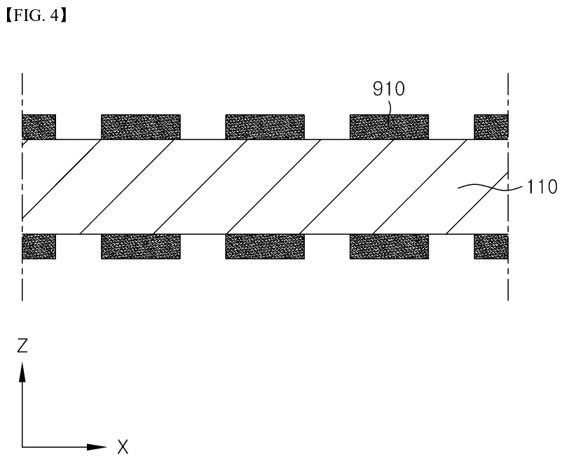

Referring further to FIG. 4, a mask pattern 910 may be formed on the silicon substrate 110. The mask pattern 910 may include a metal or may include a polymer such as a photoresist.

For example, when the mask pattern 910 is formed with a polymer photoresist, the photoresist may be applied, exposed, and developed to form the mask pattern 910. At this time, the photoresist may be either a positive photoresist or a negative photoresist.

For another example, the mask pattern 910 may also use a metal paste. At this time, the metal paste may be formed into a desired shape through printing, such as screen printing.

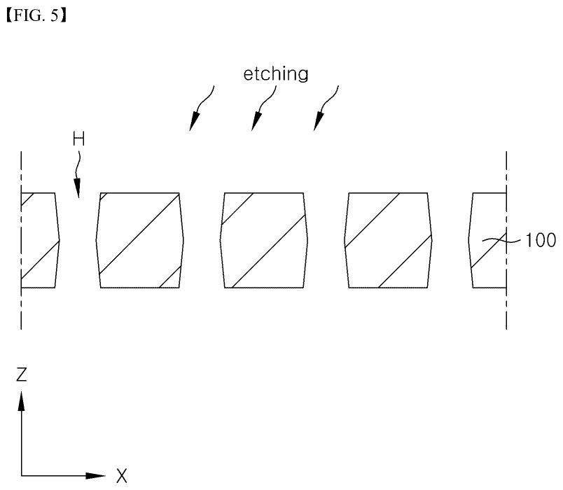

In an exemplary embodiment, the mask pattern 910 may be located on a first surface S1 (or top surface) and a second surface S2 (or bottom surface) of the silicon substrate 110. Then, a via hole formation process described below may be performed. However, the present disclosure is not limited thereto, and unlike those illustrated in FIGS. 4 and 5, a method may be used in which a mask pattern is located on the first surface S1 and a via hole is partially formed, and then a mask pattern is located again on the second surface S2 and the via hole is completely formed.

Referring further to FIG. 5, etching may be performed using the mask pattern 910 to form a silicon substrate 100 in which a via hole H is formed. Etching may be done using a wet etching process. An etchant for etching the silicon substrate 100 having the composition described above may include hydrogen fluoride (HF) and/or hydrogen peroxide (H₂O₂).

The via hole H may penetrate the silicon substrate 100 in a height direction, for example, in a third direction Z. In an exemplary embodiment, the via hole H may have an inclined inner sidewall. More specifically, the inner sidewall of the via hole H may include a first portion that is inclined toward the center from the first surface S1 and a second portion that is included toward the center from the second surface S2, but the first portion and the second portion may be inclined in opposite directions or different directions. In other words, the planar area of the via hole H may be different depending on the position of the via hole H in the third direction Z, but the area of the via hole H may be the smallest at approximately the center of the silicon substrate 100 in the third direction Z.

The maximum diameter of the via hole H may be about 30 μm or less, 20 μm or less, or 10 μm or less. The lower limit of the diameter of the via hole H is not particularly limited, but from the perspective of ease of forming a metal pattern to fill the via hole H described below, a lower limit of 5 μm or more may be desirable.

The via holes H may be repeatedly formed in a first direction X and in a second direction intersecting the first direction X. At this time, the minimum horizontal pitch between a plurality of via holes H may be about 100 μm or less, about 50 μm or less, or about 30 μm or less.

After forming the via hole H, the mask pattern 910 remaining on the silicon substrate 100 may be removed by a method such as stripping using a stripper, ashing using plasma or the like, and washing with a cleaning solution.

In another embodiment, unlike that illustrated in the drawing, when the via hole H is etched, an electric field or a magnetic field may be applied to the etchant to increase the etching speed. In still another embodiment, unlike that illustrated in the drawing, the via hole H may be formed using a laser.

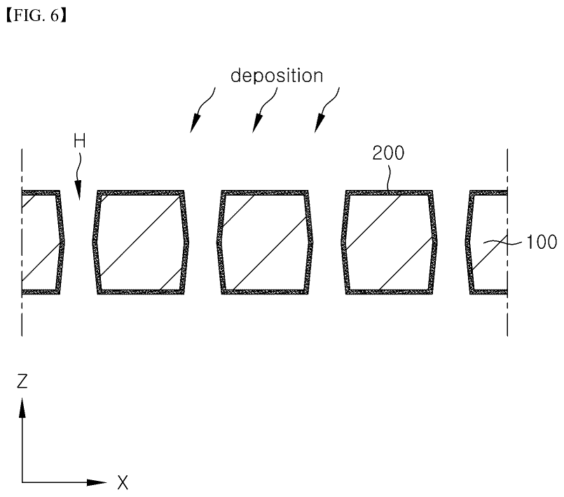

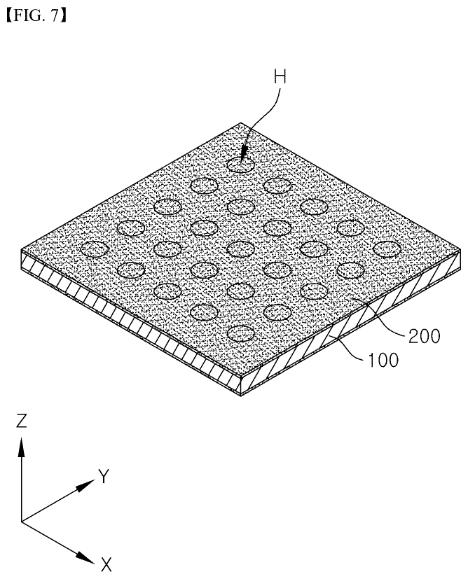

Referring further to FIGS. 6 and 7, an insulating layer 200 may be formed on the silicon substrate 100 in which the via hole H is formed. FIGS. 6 and 7 are a cross-sectional schematic diagram and a perspective view, respectively, illustrating a state in which the insulating layer 200 is formed.

The insulating layer 200 may include a material having electrical insulating properties. For example, the insulating layer 200 may include at least one of silicon dioxide (SiO₂), silicon nitride (Si₃N₄), or silicon oxynitride (SiOxNy, where x and y are the same or different numbers). As a non-limiting example, the resistivity of the insulating layer 200 may be equal to or greater than 5,000 Ω·cm. The method for forming the insulating layer 200 is not particularly limited, but, for example, deposition may be used. Specifically, plasma enhanced chemical vapor deposition (PECVD), thermal chemical vapor deposition, or the like may be used.

The insulating layer 200 may be directly in contact with the silicon substrate 100. As illustrated in FIG. 6, the insulating layer 200 may be located on both the first surface S1 and the second surface S2 of the silicon substrate 100. Additionally, the insulating layer 200 may also be located on the inner sidewall of the via hole H.

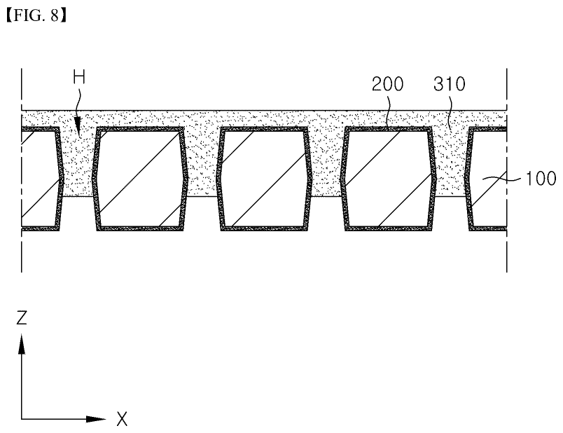

Referring further to FIG. 8, a metal layer 310 may be formed. As described below, the metal layer 310 may be patterned through a process such as etching patterning or laser patterning to form a metal pattern. At this stage, the metal layer 310 may at least partially fill the via hole H.

The method for forming the metal layer 310 is not particularly limited, but may be, for example, printing using a metal paste, e.g., screen printing. The metal layer 310 may be a metal paste including at least one of copper (Cu), silver (Ag), gold (Au), aluminum (Al), or tungsten (W).

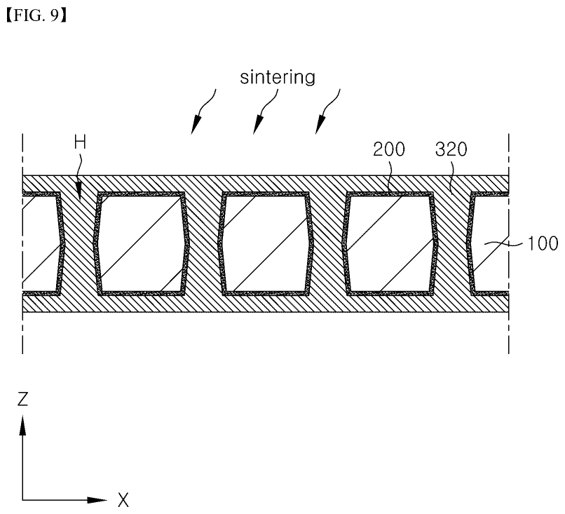

Referring further to FIG. 9, the metal layer may be further located on the second surface S2 of the silicon substrate 100 to form a hardened metal layer 320. That is, the solvent or the like included in the metal paste may be removed through a process such as sintering, and the metal layer 320 may be stabilized. The metal layer 320 formed at this time may completely, or at least partially, fill the via hole H.

FIGS. 8 and 9 illustrate a case in which the metal paste is applied from the first surface S1 of the silicon substrate 100 such that the metal paste may not completely fill the via hole H, and then the metal paste is applied from the second surface S2 and cured to form the sintered metal layer 320, but the present disclosure is not limited thereto.

Unlike that illustrated in the drawing, in some embodiments, the metal layer may be located on only one of the first surface S1 and the second surface S2. Alternatively, the metal paste may be sufficiently applied to the first surface S1 and then sintered. That is, in the state of FIG. 8, the via hole H may be completely filled with the metal paste. To this end, a vacuum may be formed on the second surface S2 to facilitate filling of the paste into the via hole H.

In still another embodiment, the metal layer may not be formed by applying and sintering a metal paste but may be formed by a method such as metal deposition, sputtering, or electroplating.

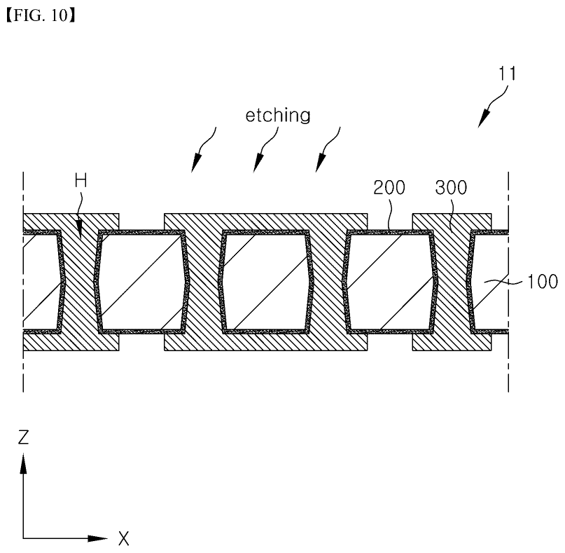

Referring further to FIG. 10, a metal pattern 300 may be formed by patterning and at least partially removing the metal layer 320. The metal pattern 300 may be formed in a plurality of pieces to be physically spaced apart from each other. The metal pattern 300 may be in contact with the insulating layer 200. In some embodiments, one of the metal patterns 300 may fill the plurality of via holes H. The metal pattern 300 may be formed to be a circuit having a desired shape to be implemented through a conductive substrate 11. Additionally, the metal pattern 300 may penetrate the via hole H to be located at least partially on the first surface S1, and located on the second surface S2. Although not illustrated in the drawing, one of the metal patterns 300 may be in contact with a first electrical element above the first surface S1 and a second electrical element below the second surface S2. At this time, the first electrical element and the second electrical element may be electrically connected through the metal pattern 300.

The method of forming the metal pattern 300 is not particularly limited, but in an exemplary embodiment, the metal pattern 300 may be formed through a process such as forming a mask pattern on the metal layer 320, partially removing the metal layer 320 by etching using the mask pattern, and then removing the mask pattern. Alternatively, in another embodiment, the metal pattern 300 may be formed by partially removing the metal layer 320 using a laser.

Through the above-described process, the conductive substrate 11 according to an embodiment of the present disclosure may be manufactured.

Although not illustrated in the drawing, the substrate may be cut to an appropriate size after forming the insulating layer 200, or after forming the metal layer 320, or after forming the metal pattern 300. For example, when a silicon substrate having a side length of several hundred millimeters or more is used as the initial silicon substrate 110, the maximum width (e.g., diameter or side length) of the conductive substrate 11 may be several millimeters or several tens of millimeters when the silicon substrate is cut.

Hereinafter, other embodiments of the present disclosure are described. However, descriptions of configurations that are substantially the same or similar to the above-described embodiments are omitted, and these will be easily understood by those skilled in the art from the accompanying drawings.

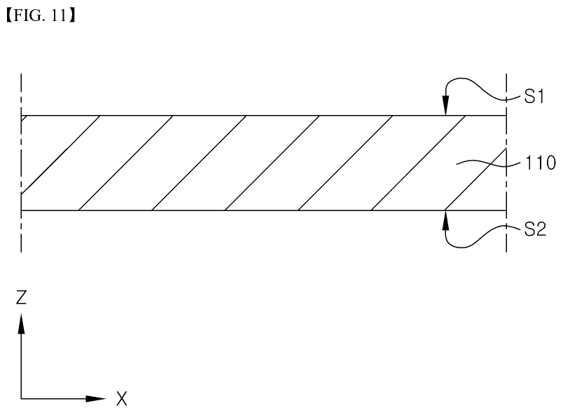

FIGS. 11 to 15 are diagrams illustrating a conductive substrate and a manufacturing method thereof according to another embodiment of the present disclosure.

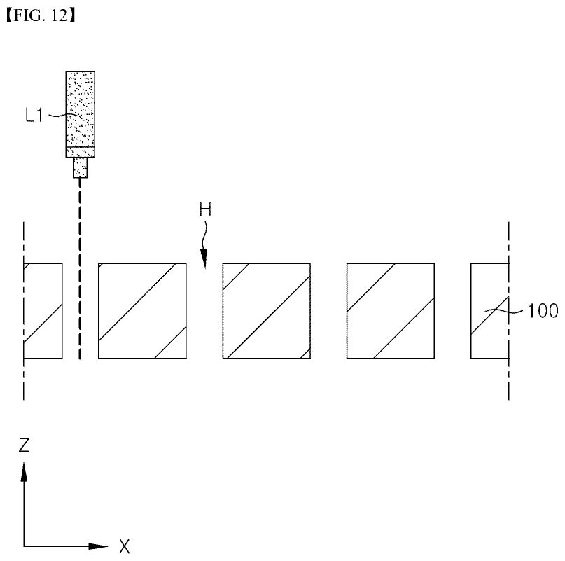

First, referring further to FIG. 11 and FIG. 12, the silicon substrate 110 may be prepared, and the via hole H may be formed.

The purity of the silicon substrate 110, the concentration and atomic number of elements included, the crystal structure, and other electrical characteristics have been described in the above-described embodiments.

According to this embodiment, when the via hole H is formed, the via hole H may be formed by irradiating a laser L1. The wavelength of the laser L1 used may be in an infrared range (e.g., approximately 750 nm to 1mm) or a near-infrared range (e.g., approximately 750 nm to 1400 nm). Specifically, a laser having one or more peak wavelengths in the near-infrared range may be used. After the laser L1 is irradiated, an etching process may be performed as needed.

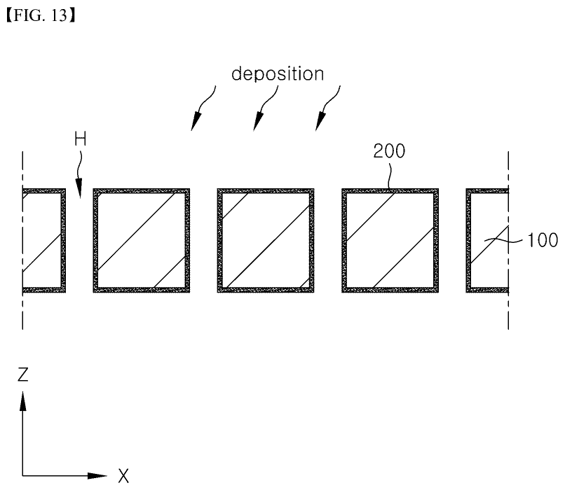

Referring further to FIG. 13, the insulating layer 200 may be formed on the silicon substrate 100 in which the via hole H is formed. The insulating layer 200 has been described in the above-described embodiments.

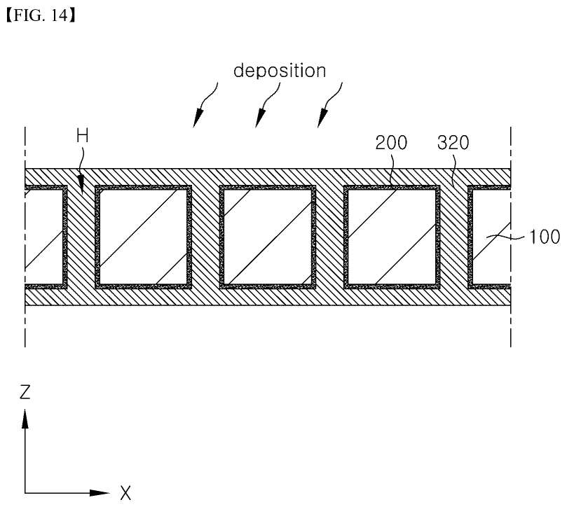

Referring further to FIG. 14, the metal layer 320 may be formed on the insulating layer 200. In this embodiment, the metal layer 320 may be formed using a metal deposition process. The material or the like of the metal layer 320 has been described in the above-described embodiments.

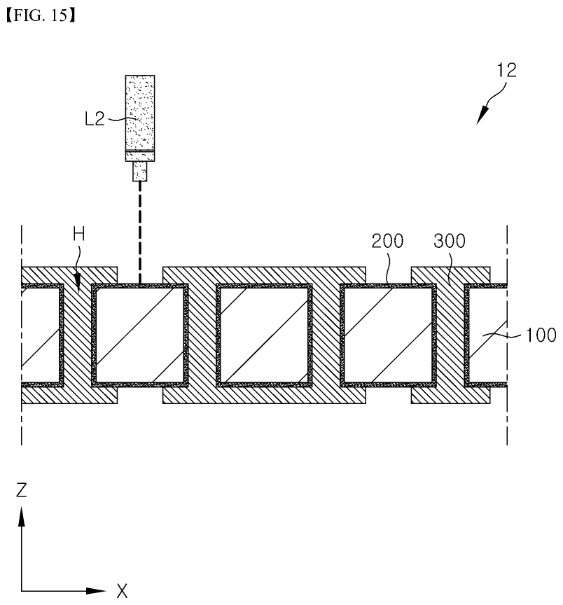

Referring further to FIG. 15, a conductive substrate 12 including the metal pattern 300 may be manufactured by at least partially removing the metal layer 320. The method of forming the metal pattern 300 may be performed by patterning with a laser L2.

According to the embodiments of FIGS. 11 to 15, unlike the embodiments of FIGS. 1 to 10 described above, the via hole H may be formed by the laser L1, the metal layer 320 may be formed by a deposition process, and the metal pattern 300 may be formed by patterning with the laser L2. However, the present disclosure is not limited thereto, and the process of the embodiments of FIGS. 1 to 10 and the process of the embodiments of FIGS. 11 to 15 may be combined.

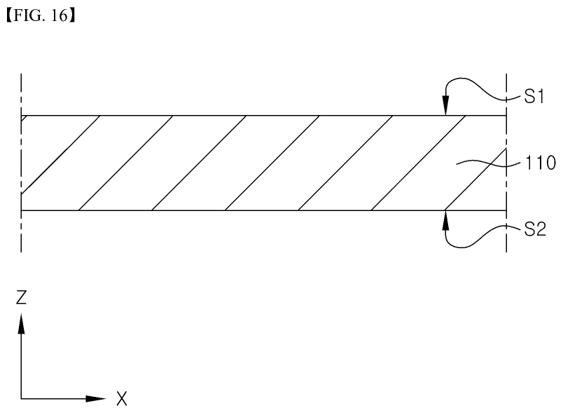

FIGS. 16 to 19 are diagrams illustrating a conductive substrate and a manufacturing method thereof according to still another embodiment of the present disclosure.

First, referring to FIG. 16, the silicon substrate 110 is prepared. The silicon substrate 110 has been described in the above-described embodiments.

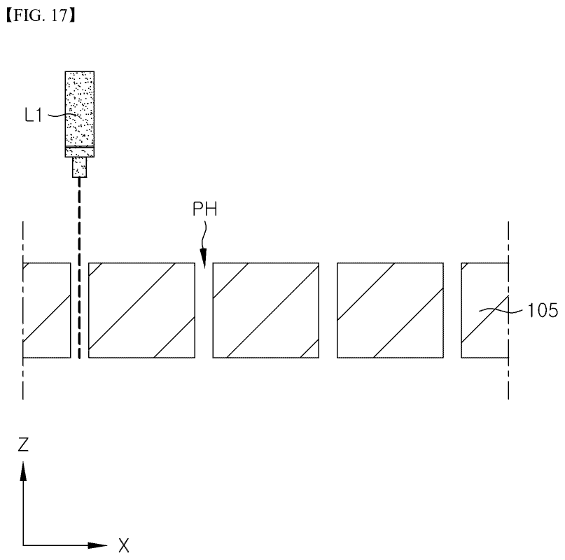

Referring further to FIG. 17, an etching hole PH may be formed in the silicon substrate 110 by using the laser L1. Here, the diameter of the etching hole PH may be about 15 μm or less, about 12 μm or less, or about 10 μm or less.

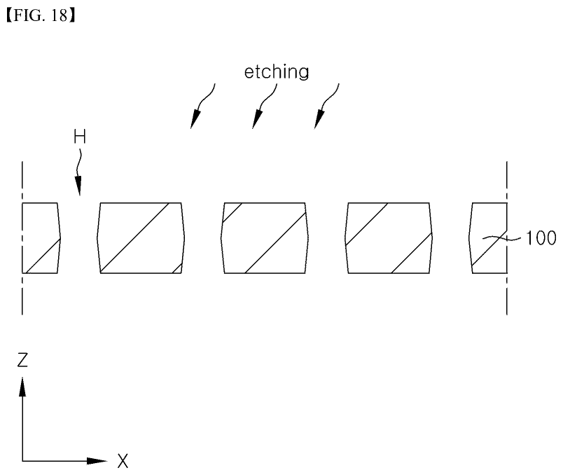

Referring further to FIG. 18, etching may be performed on a silicon substrate 105 in which the etching hole PH is formed, to form the silicon substrate 100 in which the via hole H is formed. Etching may be performed using wet etching. The etchant may permeate into the formed etching hole PH to form the via hole H having a wider diameter. For example, the maximum diameter of the via hole H expanded through the etching may be about 30 μm or less, 20 μm or less, or 10 μm or less. The lower limit of the diameter of the via hole H is not particularly limited, but from the perspective of ease of forming the metal pattern to fill the via hole H, a lower limit of 5 μm or more may be desirable. In some embodiments, the top surface and/or bottom surface of the silicon substrate 100 may also be partially etched when an etching mask is not formed.

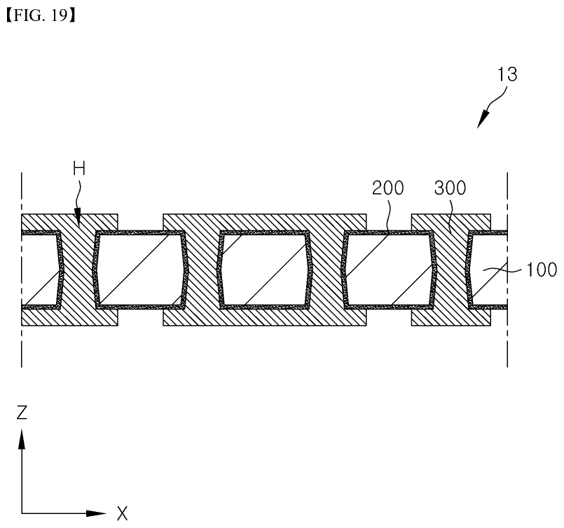

Referring to FIG. 19, a conductive substrate 13 including the insulating layer 200 and the metal pattern 300 may be manufactured on the silicon substrate 100. Since the formation of the insulating layer 200 and the metal pattern 300 has been described above, a description thereof will be omitted. That is, a metal layer may be formed by coating, depositing, or plating a metal paste, and the metal pattern 300 may be formed using etching and/or laser patterning. In some embodiments, a process of planarizing the metal layer by performing a chemical mechanical polishing (CMP) process before forming the metal pattern 300 may be performed.

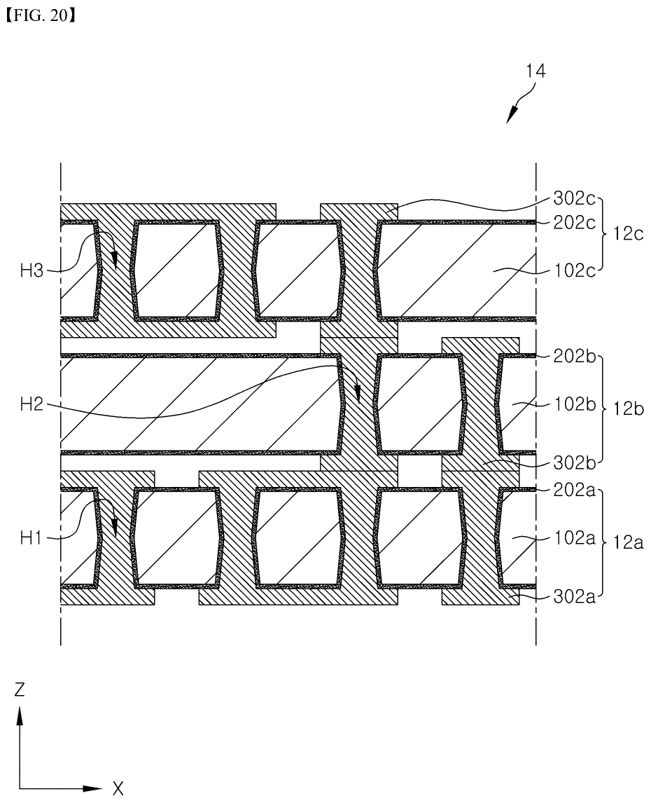

FIG. 20 is a cross-sectional schematic diagram of a conductive substrate according to still another embodiment of the present disclosure.

Referring to FIG. 20, a conductive substrate 14 (or conductive substrate laminate) according to this embodiment differs from the embodiment of FIG. 10 described above in that a first silicon substrate 102a, a second silicon substrate 102b, and a third silicon substrate 102c are included, and a first insulating layer 202a to a third insulating layer 202c and a first metal pattern 302a to a third metal pattern 302c are further included.

The first silicon substrate 102a to the third silicon substrate 102c may be stacked and overlapped in the third direction Z. The first silicon substrate 102a to the third silicon substrate 102c may be spaced apart and physically separated. At least part or all of the first silicon substrate 102a to the third silicon substrate 102c may be silicon substrates that are undoped, or are regionally non-uniformly doped by being only partially doped. The first silicon substrate 102a to the third silicon substrate 102c may have a first via hole H1, a second via hole H2, and a third via hole H3, respectively. The first silicon substrate 102a to the third silicon substrate 102c may be substantially the same as the silicon substrate of the embodiments of FIG. 10 and the like described above.

The first insulating layer 202a, the second insulating layer 202b, and the third insulating layer 202c may be located on the first silicon substrate 102a to the third silicon substrate 102c, respectively. The first insulating layer 202a to the third insulating layer 202c may be substantially the same as the insulating layer of the embodiments of FIG. 10 and the like described above.

The first metal pattern 302a, the second metal pattern 302b, and the third metal pattern 302c may be located on the first insulating layer 202a to the third insulating layer 202c, respectively. The first metal pattern 302a to the third metal pattern 302c may be at least partially located within the first via hole H1 to the third via hole H3, respectively. The first metal pattern 302a to the third metal pattern 302c may be substantially the same as the metal pattern of the embodiments of FIG. 10 and the like described above.

The conductive substrate 14 (or conductive substrate laminate) according to this embodiment may be manufactured by manufacturing each of a first conductive substrate 12a, a second conductive substrate 12b, and/or a third conductive substrate 12c by the process of FIGS. 1 to 10, or the process of FIGS. 11 to 15, or the process of FIGS. 16 to 19, and then laminating and positioning them as shown in FIG. 20, for example.

In some embodiments, the metal patterns of the conductive substrates that are adjacent to each other in a stacking direction, that is, the third direction Z, may be in contact with each other. For example, an upper portion of the first metal pattern 302a of the first conductive substrate 12a may be at least partially in contact with a lower portion of the second metal pattern 302b of the second conductive substrate 12b. Additionally, an upper portion of the second metal pattern 302b of the second conductive substrate 12b may be at least partially in contact with a lower portion of the third metal pattern 302c of the third conductive substrate 12c.

Additionally, at least some of the first via holes H1 to the third via holes H3 may be aligned in the third direction Z, and at least some may not be aligned in the third direction Z. According to this embodiment, the first conductive substrate 12a to the third conductive substrate 12c including metal patterns having different shapes may be stacked to provide diversified electrical paths.

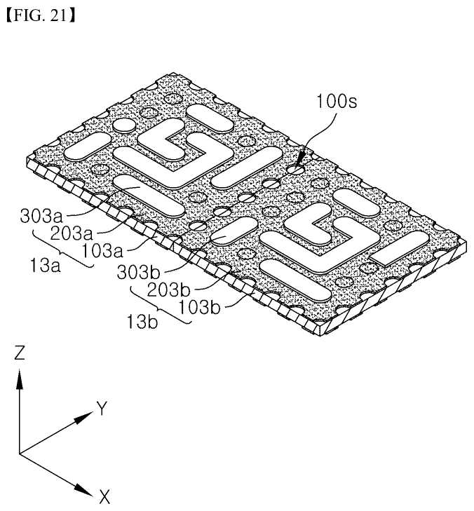

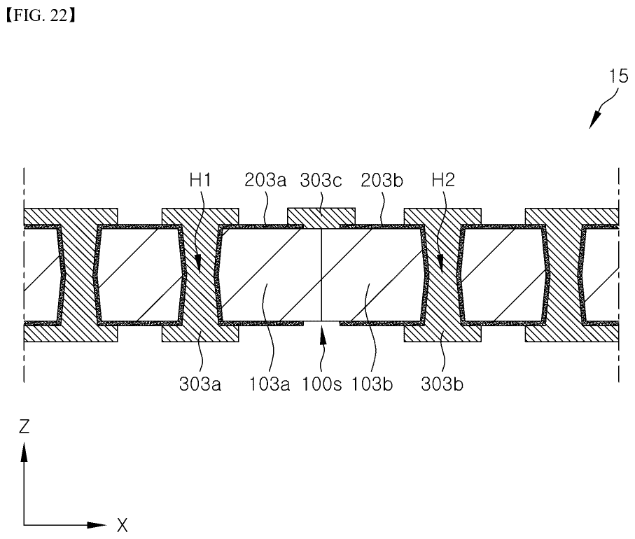

FIGS. 21 and 22 are diagrams illustrating a conductive substrate and a manufacturing method thereof according to still another embodiment of the present disclosure. Specifically, FIG. 22 is a cross-sectional view illustrating the vicinity of the boundary between a first conductive substrate 13a and a second conductive substrate 13b of FIG. 21. FIG. 21 omits the illustration of a third connection metal pattern 303c.

Referring to FIGS. 21 and 22, the conductive substrate 15 (or conductive substrate assembly) according to this embodiment may include the first conductive substrate 13a and the second conductive substrate 13b, but may further include the connection metal pattern 303c (or third metal pattern).

The first conductive substrate 13a may include a first silicon substrate 103a, a first insulating layer 203a located on the first silicon substrate 103a, and a first metal pattern 303a located on the first insulating layer 203a. Additionally, the second conductive substrate 13b may include a second silicon substrate 103b, a second insulating layer 203b located on the second silicon substrate 103b, and a second metal pattern 303b located on the second insulating layer 203b.

The first silicon substrate 103a and the second silicon substrate 103b may be arranged in a horizontal direction, for example, in the first direction X, and may be in contact with each other. The first silicon substrate 103a and the second silicon substrate 103b may be at least partially in contact with each other and physically separated. At least part or all of the first silicon substrate 103a and the second silicon substrate 103b may be silicon substrates that are undoped, or are regionally non-uniformly doped by being only partially doped. The first silicon substrate 103a and the second silicon substrate 103b may have the first via hole H1 and the second via hole H2, respectively. The first silicon substrate 103a and the second silicon substrate 103b may be substantially the same as the silicon substrate of the embodiments of FIG. 10 and the like described above.

The first insulating layer 203a and the second insulating layer 203b may be located on the first silicon substrate 103a and the second silicon substrate 103b, respectively. The first insulating layer 203a and the second insulating layer 203b may be substantially the same as the insulating layer of the embodiments of FIG. 10 and the like described above.

The first metal pattern 303a and the second metal pattern 303b may be located on the first insulating layer 203a and the second insulating layer 203b, respectively. The first metal pattern 303a and the second metal pattern 303b may be located at least partially within the first via hole H1 and the second via hole H2, respectively. The first metal pattern 303a and the second metal pattern 303b may be substantially the same as the metal pattern of the embodiments of FIG. 10 and the like described above.

The conductive substrate 15 according to this embodiment may be manufactured by preparing each of the first conductive substrate 13a including the first metal pattern 303a and the second conductive substrate 13b including the second metal pattern 303b by the process of FIGS. 1 to 10, or the process of FIGS. 11 to 15, or the process of FIGS. 16 to 19 described above, then positioning them in the first direction X as illustrated in FIG. 21, and forming the connection metal pattern 303c as illustrated in FIG. 22. The connection metal pattern 303c may include a material that is the same as or different from those of the first metal pattern 303a and the second metal pattern 303b. In addition, the method of forming the connection metal pattern 303c may include sintering a metal paste or may include depositing a metal layer and then performing a patterning process such as etching.

In another embodiment, the connection metal pattern 303c may include the same material as the first metal pattern 303a and the second metal pattern 303b and may be formed together with the first metal pattern 303a and the second metal pattern 303b. For example, after the first insulating layer 203a is formed on the first silicon substrate 103a and the second insulating layer 203b is formed on the second silicon substrate 103b, the first metal pattern 303a, the second metal pattern 303b, and the connection metal pattern 303c may be formed in a single process while they are connected.

In an exemplary embodiment, an edge-side top surface of the first silicon substrate 103a in the first direction X may be exposed without being covered at least partially by the first insulating layer 203a, and similarly, an edge-side top surface of the second silicon substrate 103b in the first direction X may be exposed without being covered at least partially by the second insulating layer 203b.

Further, one of the connection metal patterns 303c may be directly in contact with the top surface of the first silicon substrate 103a and the top surface of the second silicon substrate 103b. FIG. 22 illustrates a case where the connection metal pattern 303c is located only on an upper exposed surface 100s of the first silicon substrate 103a and the second silicon substrate 103b, but a connection metal pattern may also be formed on a lower exposed surface 100s.

Additionally, the connection metal pattern 303c may be at least partially in contact with the first insulating layer 203a and the second insulating layer 203b. Additionally, the connection metal pattern 303c may overlap the first silicon substrate 103a and the second silicon substrate 103b simultaneously in the third direction Z.

Unlike that illustrated in the drawing, one of the connection metal patterns 303c may be in contact with and be electrically connected to the first metal pattern 303a and/or the second metal pattern 303b.

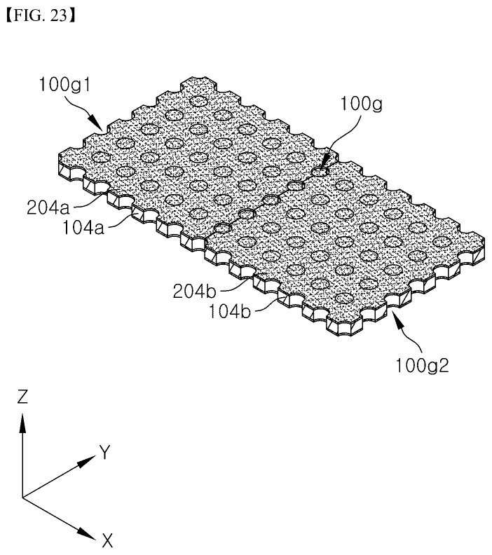

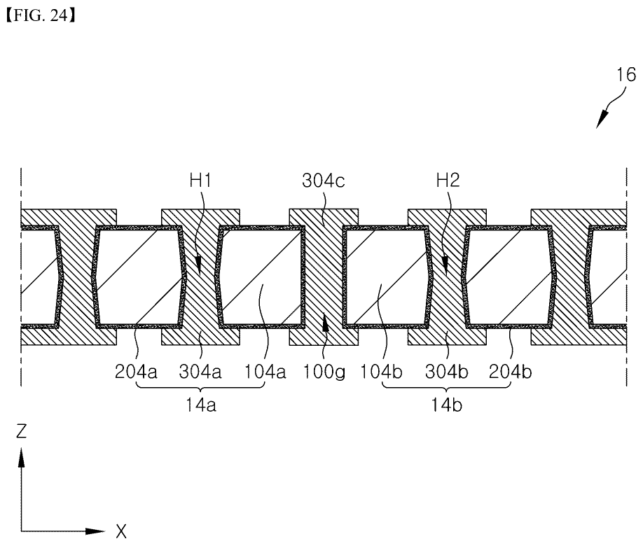

FIGS. 23 and 24 are diagrams illustrating a conductive substrate and a manufacturing method thereof according to still another embodiment of the present disclosure. Specifically, FIG. 24 is a cross-sectional view illustrating the vicinity of the boundary between a first conductive substrate 14a and a second conductive substrate 14b of FIG. 23.

Referring to FIGS. 23 and 24, a conductive substrate 16 (or conductive substrate assembly) according to this embodiment differs from the embodiment of FIG. 22 in that a first conductive substrate 14a, second conductive substrate 14b, and connection metal pattern 304c (or third metal pattern) are included, and the connection metal pattern 304c is located between the first silicon substrate 104a and the second silicon substrate 104b.

The first conductive substrate 14a and the second conductive substrate 14b have been described with reference with FIG. 21 and the like.

In this embodiment, the edge of the first silicon substrate 104a in the first direction X may have a first groove 100g1, and the edge of the second silicon substrate 104b in the first direction X may have a second groove 100g2. FIG. 23 illustrates a case where each of the first groove 100g1 and the second groove 100g2 has an approximately semicircular shape in plan view, but the present disclosure is not limited thereto.

The first silicon substrate 104a and the second silicon substrate 104b may be arranged in a horizontal direction, for example, in the first direction X. At this time, the first groove 100g1 of the first silicon substrate 104a and the second groove 100g2 of the second silicon substrate 104b may face each other, and the first groove 100g1 and the second groove 100g2 may together form a coupling hole 100g. The coupling hole 100g may have a shape that penetrates the upper and lower parts. In some embodiments, a first insulating layer 204a may be located on the first groove 100g1, a second insulating layer 204b may be located on the second groove 100g2, and the connection metal pattern 304c may be located between the first insulating layer 204a and the second insulating layer 204b.

In the conductive substrate 16 according to this embodiment, the first insulating layer 204a may be formed on the first silicon substrate 104a, the second insulating layer 204b may be formed on the second silicon substrate 104b, and they may be arranged in the first direction X as illustrated in FIG. 23. Then, as illustrated in FIG. 24, it may be manufactured by forming a first metal pattern 304a, a second metal pattern 304b, and the connection metal pattern 304c. In some embodiments, the first metal pattern 304a, the second metal pattern 304b, and the connection metal pattern 304c may include the same material and may be formed in one process.

In another embodiment, the conductive substrate 16 may be manufactured by preparing each of the first conductive substrate 14a including the first metal pattern 304a and the second conductive substrate 14b including the second metal pattern 304b by the process of FIGS. 1 to 10, or the process of FIGS. 11 to 15, or the process of FIGS. 16 to 19 described above, and then arranging them in the first direction X and forming the connection metal pattern 304c.

In an exemplary embodiment, one of the connection metal patterns 304c may be directly in contact with the first insulating layer 204a and the second insulating layer 204b simultaneously. In addition, the connection metal pattern 304c may overlap the first silicon substrate 104a, the first insulating layer 204a, the first metal pattern 304a, the second silicon substrate 104b, the second insulating layer 204b, and the second metal pattern 304b in the first direction X.

Unlike that illustrated in the drawing, the connection metal pattern 304c may be directly in contact with the first silicon substrate 104a and the second silicon substrate 104b, and/or may be in contact with and be connected to the first metal pattern 304a or the second metal pattern 304b.

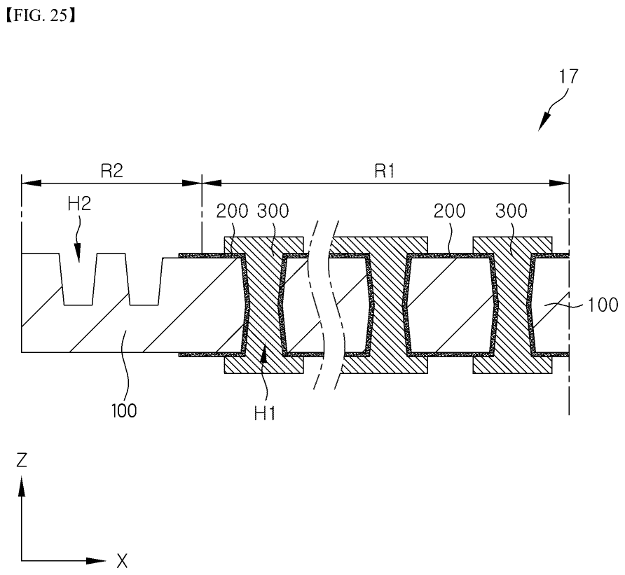

FIG. 25 is a cross-sectional schematic diagram of a conductive substrate according to still another embodiment of the present disclosure.

Referring to FIG. 25, a conductive substrate 17 according to this embodiment may include the silicon substrate 100, the insulating layer 200, and the metal pattern 300. At this time, a first region R1 and a second region R2 may be defined in the conductive substrate 17. In plan view, the second region R2 may be positioned at the edge relative to the first region R1. As a non-limiting example, when the conductive substrate 17 has a circular shape in plan view, the second region R2 may be a ring-shaped region at the edge. Alternatively, when the conductive substrate 17 has a quadrilateral shape in plan view, the second region R2 may be a quadrilateral ring-shaped region at the edge.

The insulating layer 200 and/or the metal pattern 300 may be located in the first region R1. On the other hand, at least the metal pattern 300 may be absent in the second region R2. For example, a region where the metal pattern 300 is present may be defined as the first region R1, and a region where the metal pattern 300 is not present may be defined as the second region R2. Here, the metal pattern 300 may mean a metal pattern filled in the via hole H1.

In addition, although FIG. 25 exemplifies a case where the insulating layer 200 is partially present within the second region R2, in another embodiment, the first region R1 may be defined as a region where the insulating layer 200 is present, and the second region R2 may be defined as a region where the insulating layer is not present. In other words, a region where at least one, or both, of the top surface and/or bottom surface of the silicon substrate 100 are exposed may be defined as the second region R2.

With respect to the first region R1, it may be substantially the same as described above. That is, the silicon substrate 100 may have the via hole H1, and the insulating layer 200 may be located on the silicon substrate 100. Further, the via hole H1 may be filled, and the metal pattern 300 may be located on the top surface and bottom surface of the silicon substrate 100.

A recessed groove H2 may be formed in the second region R2. The recessed groove H2 may not have a shape that completely penetrates the silicon substrate 100, but may have a concave recess shape. FIG. 25 illustrates a case where the recessed groove H2 is formed on a top surface of the silicon substrate 100. The recessed groove H2 may be formed together with the formation of the via hole H1. The method for forming the recessed groove H2 is not particularly limited, but etching and/or laser processes using a mask pattern may be used. Within the recessed groove H2, a component referred to as an insulating layer and/or a metal pattern may not be present.

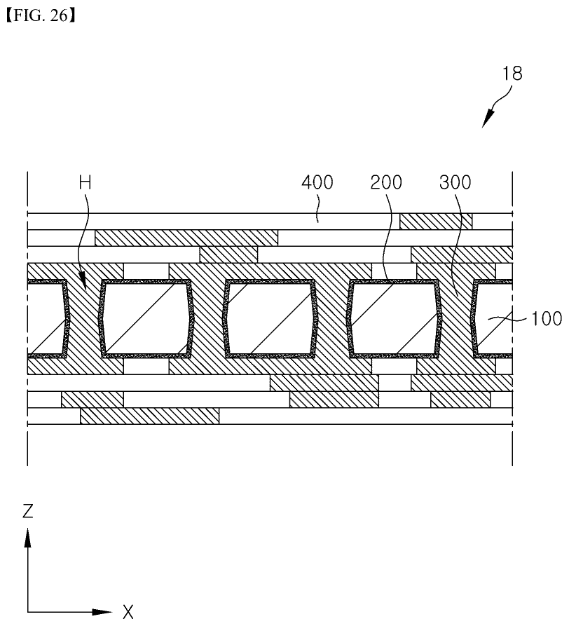

FIG. 26 is a cross-sectional schematic diagram of a conductive substrate according to still another embodiment of the present disclosure.

Referring to FIG. 26, a conductive substrate 18 according to this embodiment may include the silicon substrate 100, the first insulating layer 200, and the metal pattern 300, but may further include a second insulating layer 400.

It may be understood that the first insulating layer 200 is an insulating layer that is directly in contact with the silicon substrate 100 and is located within the via hole H. On the other hand, the second insulating layer 400 may be defined as an insulating layer that is not directly in contact with the silicon substrate 100.

The metal pattern 300 may be located within the via hole H and may be located on the top surface and/or bottom surface of the silicon substrate 100. At this time, the metal pattern 300 may be formed in a plurality of layers. Additionally, the second insulating layer 400 may be located between the metal patterns 300 stacked in a plurality of layers. The second insulating layer 400 may be provided for insulation between the metal patterns 300. The material of the second insulating layer 400 may be the same as or different from that of the first insulating layer 200.

Although the preferred embodiments have been described above, they are merely examples and not intended to limit any embodiments and it should be appreciated that various modifications and applications not described above may be made by one of ordinary skill in the art without departing from the embodiments.

Therefore, it should be understood that the scope of the present disclosure includes changes, equivalents or substitutes of the technical concept described above. For example, each component specifically shown in the embodiment of the present disclosure may be modified and implemented. In addition, it should be understood that differences related to these modifications and applications are within the scope of the present disclosure.

1. A silicon-based conductive substrate comprising:
an undoped or regionally non-uniformly doped silicon substrate;
an insulating layer located on the silicon substrate; and
a metal pattern located on the insulating layer.

2. The conductive substrate of claim 1, wherein the silicon substrate is an undoped silicon substrate, and
a silicon purity of the silicon substrate is 99.99999999% or less.

3. The conductive substrate of claim 2, wherein the silicon substrate does not substantially contain a boron (B) element and phosphorus (P) element.

4. The conductive substrate of claim 3, wherein the silicon substrate has a polycrystalline structure, and the purity of the silicon substrate is 99.99% or more.

5. The conductive substrate of claim 1, wherein the silicon substrate is partially doped with boron (B) or phosphorus (P) to become a non-uniformly doped silicon substrate.

6. The conductive substrate of claim 1, wherein the silicon substrate contains a nitrogen (N) or oxygen (O) element, and a resistivity of the silicon substrate ranges from several hundred Ω·cm to several thousand Ω·cm.

7. The conductive substrate of claim 6, wherein the silicon substrate has a band gap of 9.1 eV or more, or a breakdown voltage of 10 MV/cm or more.

8. The conductive substrate of claim 1, wherein the insulating layer contains at least one of silicon dioxide (SiO₂), silicon nitride (Si₃N₄), or silicon oxynitride (SiOxNy, where x and y are the same or different numbers).

9. The conductive substrate of claim 1, wherein the metal pattern contains at least one of copper (Cu), silver (Ag), gold (Au), aluminum (Al), or tungsten (W).

10. The conductive substrate of claim 1, wherein the silicon substrate has a via hole, the insulating layer is located on an inner sidewall of the via hole, and the metal pattern is located within the via hole.

11. The conductive substrate of claim 10, wherein the metal pattern is arranged on a first surface and a second surface of the silicon substrate, and the metal pattern on the first surface and the metal pattern on the second surface are electrically connected to each other.

12. The conductive substrate of claim 1, wherein the metal pattern is formed by laser patterning.

13. The conductive substrate of claim 1, wherein the metal pattern is formed by printing a metal paste.

14. The conductive substrate of claim 1, wherein the silicon substrate comprises a first silicon substrate and a second silicon substrate physically separated from the first silicon substrate,
the insulating layer comprises a first insulating layer located on the first silicon substrate and a second insulating layer located on the second silicon substrate,
the metal pattern comprises a first metal pattern in contact with the first insulating layer, and a second metal pattern in contact with the second insulating layer, and
the metal pattern further comprises a third metal pattern in contact with the first silicon substrate and the second silicon substrate, or located between the first silicon substrate and the second silicon substrate.

15. The conductive substrate of claim 14, wherein the third metal pattern is in contact with a top surface of the first silicon substrate and a top surface of the second silicon substrate.

16. The conductive substrate of claim 14, wherein a first groove is formed on a surface of the first silicon substrate facing the second silicon substrate,
a second groove is formed on a surface of the second silicon substrate facing the first silicon substrate,
the first groove and the second groove together form a coupling hole, and
the third metal pattern is filled in the coupling hole.

17. The conductive substrate of claim 1, wherein the silicon substrate comprises a first silicon substrate and a second silicon substrate physically separated from the first silicon substrate and stacked on the first silicon substrate,
the insulating layer comprises a first insulating layer located on the first silicon substrate and a second insulating layer located on the second silicon substrate,
the metal pattern comprises a first metal pattern in contact with the first insulating layer, and a second metal pattern in contact with the second insulating layer, and
the first metal pattern and the second metal pattern are at least partially in contact with each other and electrically connected.

18. The conductive substrate of claim 17, wherein the first silicon substrate and the second silicon substrate each have a first via hole and a second via hole, and
at least some of the first via hole and the second via hole are matched and aligned in the stacking direction or are mismatched and misaligned.

19. A manufacturing method of a conductive substrate, comprising:
preparing an undoped or regionally non-uniformly doped silicon substrate;
placing an insulating layer on the silicon substrate; and
placing a metal pattern on the insulating layer.
